(19) United States
(12) Patent Application Publication
(10) Pub. No.: US 2021/0046567 A1
(43) Pub. Date: Feb. 18, 2021

(54) REFLOW CONDENSATION SOLDERING MACHINE

(71) Applicant: Rehm Thermal Systems GmbH, Blaubeuren-Seissen (DE)

(72) Inventors: Paul WILD, Blaubeuren-Seissen (DE); Karin Krauss, Blaubeuren-Seissen (DE)

(21) Appl. No.: 16/985,334

(22) Filed: Aug. 5, 2020

(30) Foreign Application Priority Data
Aug. 14, 2019 (DE) 102019212161.6

(51) Int. Cl. B23K 1/015; H05K 3/34

(52) U.S. Cl. CPC B23K 1/015; B23K 2101/42; H05K 3/3494

(57) ABSTRACT

Reflow condensation soldering machine comprising a circulation system for a heat transfer medium, the reflow condensation soldering machine comprising the circulation system, a centrifuge and a condensation device for the heat transfer medium.

### FIELD OF THE INVENTION

The present invention refers to a reflow condensation soldering machine and furthermore to a method for operating the reflow condensation soldering machine.

### STATE OF THE ART

As is well known, condensation soldering, also known as vapor phase soldering, releases energy in the form of heat when a saturated vapor phase condenses on the surface of a component to be soldered, whereby the solder melts, thus creating the connection between the component and the strip conductor. The saturated vapor phase is generated by a boiling heat transfer liquid, whereby the boiling point of the heat transfer liquid determines the process temperature during the soldering process. The preferred heat transfer fluid is usually perfluoropolyether (PFPE), a group of plastics that are usually liquid to pasty at room temperature. In particular, a perfluoropolyether with a boiling point of e.g. 260° C. is used for vapor phase soldering, also known as and sold under the trademark Galden HS260 (HS260=260° C. boiling point). During reflow soldering, the Galden is loaded with the condensates and other waste products (collectively referred to as residuals) and forms an emulsion with them. In order to save costs and protect the environment, this emulsion is recycled, i.e. the Galden is separated from the residuals so that the Galden can be fed back into the soldering process.

In state-of-the-art plants, the heat transfer medium is not found in a closed circuit, but condenses in the same container in which the steam is produced by heating. Such a plant is described as an example in the publication of the French patent application FR2499228. Such plants comprise at least one process chamber which is partially filled with the PFPE. Heating resistors heat the PFPE to boiling point. The hot PFPE steam condenses on the assembly to be soldered and heats the assembly to the melting point of the solder applied to the assembly. The assembly is then cooled and removed from the process chamber so that a new soldering process can be started with a new assembly to be soldered. After a series of soldering operations, the PFPE is purified. The purification of the PFPE is not continuous, but takes place in longer maintenance cycles. The interval between each purification cycle must be reduced as the throughput increases. At the same time, less pure PFPE is available for the process towards the end of the maintenance cycle and at the same time bitumen or tar-like residuals can collect at the bottom of the tank, which are also very costly to remove.

In order to keep the impurities in the process chamber small, the PFPE is kept in a circuit in the more modern systems, such as the Condenso series from REHM Thermal Systems GmbH. FIG. 1 shows schematically some essential components of a reflow condensation soldering machine 100 with a circulation system 110 for a heat transfer medium as used in the Condenso series of REHM Thermal Systems GmbH. FIG. 1 shows a pump 20, which transports the liquid PFPE from a reservoir 10 to a heating means 30. In the heating means 30 the PFPE is vaporized and then fed to a process chamber 40. The medium (vaporous PFPE) then condenses and thus heats the components to be soldered on a printed circuit board 45 in the process chamber 40. Due to the boiling point of the PFPE, the maximum soldering temperature is simultaneously reached. In a subsequent regeneration phase (separation phase) for the PFPE, the heat transfer medium (both portions in vaporous and liquid aggregate state) is sucked out of chamber 40 with a pump 50. After suction, the portion of the heat transfer medium in the vaporous aggregate state is condensed in a condenser 60. The result is an emulsion of impurities and the original liquid, since the fluxes and soldering pastes used in the soldering process, as well as impurities that come through the printed circuit board 45 into the process chamber 40, are sucked off together with the heat transfer medium. The emulsion is collected in a collection tank 70, where a first sedimentation of the PFPE takes place due to its high density (ρ=1.83 g/cm3). Then a further purification stage takes place through a filter box 80 before the filtered and purified PFPE is collected in the storage tank or reservoir 10, from where it is re-injected into the process chamber 40. Conventional filter mats, granulate filters and/or activated carbon filters are used as filters. Particle separation with Venturi nozzles proved to be useless.

A plant similar to FIG. 1 is described as an example in European patent specification EP 1157771 B2. Contrary to FIG. 1, in the plant described in EP 1157771 B2 only the condensate is drained and filtered from the process chamber, which means that the system described in EP 1157771 B2 may be simpler than that shown in FIG. 1, but requires more frequent purification or maintenance.

An increase in throughput leads to a shorter dwell time in the collection tank. This in turn means that the sedimentation of the PFPE is less complete, resulting in a greater carry-over of impurities and a complete purification and filtering of the heat transfer medium can no longer be guaranteed.

It is therefore an object of the present invention to improve the purification performance in the circuit.

### SUMMARY OF THE INVENTION

In order to fulfill this object, a reflow condensation soldering machine according to an embodiment is provided. The claimed reflow condensation soldering machine is equipped with a circulation system of a heat transfer medium, said circulation system comprising a centrifuge and a condensation device for the heat transfer medium. Through the circulation system, the impurities are pumped off after each soldering process for, for example for a printed circuit board, so that clean heat transfer medium is available for the soldering process of the next printed circuit board. In addition, the heat transfer medium condensation device in combination with the centrifuge allows the heat transfer medium of a process run to be recovered efficiently, i.e. effectively with a high separation rate, almost completely for reuse. This results in cost advantages, especially when using relatively expensive Galden as heat transfer medium. In addition, less chemical waste is produced and the environment is protected.

In a special embodiment, the centrifuge is a disc separator, a special type of centrifuge. Disc centrifuges or disc separators are particularly suitable for separating suspensions with one or a plurality of liquid phases and with small particles. The discs increase the surface area on which the different phases can settle, which can considerably accelerate the separation process. In the following, the invention is explained by means of disc separators. However, it should be noted that the present invention can generally be carried out with centrifuges and that the use of disc separators makes the separation process more efficient.

According to different embodiments, the number of discs, the disc spacing, the speed of rotation and the volume of the disc separator can be configured to achieve a desired plant throughput, taking into account expected particle sizes of impurities in the heat transfer medium and viscosity of the contaminated heat transfer medium.

The number, shape, structure and arrangement of the discs are variable within wide limits and can be adapted to the substances to be separated in the suspension. For example, the number of discs and the speed of rotation influences the separation speed. For example, in certain embodiments the disc separator can have 4 to 250 discs. For applications in condensation plants, the disc separator should preferably have at least 250 discs, with a disc spacing in the range of 0.2 mm-14 mm, and the discs being equally spaced. If the particle sizes vary considerably, it may also be advantageous for the disc spacing in the inlet area to be smaller or larger than at the end of the disc stack opposite the inlet area. The distribution of the spacing in the disc stack can also depend on the different densities of impurity particles of a certain size. Furthermore, the disc separator can be adapted to perform 1-150,000 rotations per minute, preferably 1000 to 10,000 rotations per minute. The disc separator can be adapted to process 2-6 liters of condensed, used heat transfer medium, which corresponds to a plant size with a filling capacity of 20-40 liters.

The number of discs, the volume of the disc separator, the disc spacing and the speed of rotation are designed to match the plant throughput. For example, if 10 reflow processes are to take place per hour, the plant must be dimensioned so that the heat transfer medium used can be purified 10 times per hour.

In one embodiment, the condensation device for the heat transfer medium is integrated in the disc separator. By integrating these two components, the separation of the PFPE from the impurities is accelerated. The separator fulfills a double function: vaporous heat transfer medium is condensed and impurities contained in the condensate are separated. Since the impurities and the heat transfer medium have different condensation points, separation of the components already occurs during condensation, which is maintained and enhanced by the rotation of the disc separator. This speeds up the separation and the regenerated heat transfer medium can be made available to a soldering process more quickly and, if necessary, with a higher degree of purity. This means that an increase in the plant throughput is made possible.

Integration of the condensation device in the separator can be achieved, for example, by a temperature limiting means of one or a plurality of components of the disc separator. For example, a disc separator may include the following components: an inlet, a float, one or a plurality of discs, and a drum that accommodates the rotating discs. The temperature limiting means may include active or passive cooling of one or more components of the disc separator.

In an embodiment, the temperature limiting means is an active cooling system in which, for example, a wall of one or a plurality of components has at least one cavity through which a cooling fluid can flow.

In an alternative embodiment, the device for limiting the temperature is an active cooling system, whereby a heat pipe is integrated in one wall of one or plurality of components. Compared to the aforementioned cooling system with a cooling fluid, a heat pipe has the advantage that no cooling circuit with cooling fluid has to be provided.

In a further embodiment, the temperature limiting means is a passive cooling system, wherein at least one component of the one or plurality of components is adapted such that a heat capacity of the at least one component is sufficient to absorb a quantity of heat of the vaporous heat transfer medium flowing past during a predetermined separation phase, so that the heat transfer medium condenses. The materials, the dimensions (size, dimensions, mass) and the flow geometries of these components are selected in such a way that the amount of heat released during the condensation of the entire vaporous heat transfer medium present in the process chamber can be absorbed by the component(s). It is also possible to combine this with a process control system that adjusts the timing of the soldering phases and regeneration phases (separation phases), the flow rate of the heat transfer medium through the separator and the cooling times for the separator components so that almost all of the vaporous heat transfer medium in the process chamber can condense and at the same time the heat absorbed by the separator components can be released again. With passive cooling, no additional components are required for cooling, so the disc separator has fewer components that are easier to maintain.

Passive cooling is favored by the fact that the soldering phase and regeneration phase (of the heat transfer medium) are carried out one after the other. Since no vaporous heat transfer medium is fed into the condensation device during the soldering phase, the condensation device or the separating condensate trap can cool down during this time (soldering phase). This means that vapor is only supplied after the end of the soldering phase (into the process chamber). During the soldering process (in the process chamber) no vapor is supplied to the disc separator, so that the components on which condensation takes place can cool down (cooling phase of the separating condensate trap). The disc separator can also continue to run continuously, even in the cooling phase when no vapor is supplied. In this case, the previously separated PFPE can be fed again during the cooling phase. Three advantages are thus achieved. Firstly, the disc separator is cooled with the liquid PFPE. Secondly, the degree of purity of the PFPE is improved. Furthermore, it prevents the disc separator from running dry. This means that since the hydrodynamic conditions for separation are only optimal when the disc separator is filled, the disc separator runs most efficiently in the filled state.

Correspondingly, in a further embodiment, the circulation system for the heat transfer medium of the reflow condensation soldering machine still has a device with which purified PFPE can be fed to the centrifuge during a cooling phase of passive cooling.

In another embodiment, the heat transfer medium has a boiling point of 260° C. Since commercially available solders have a melting point of less than 260° C., commercially available solders can be used without overheating the components to be soldered.

Galden is preferably used as the heat transfer medium. Galden is the common name for the heat transfer medium “perfluoropolyether”, which has a number of advantageous properties for reflow condensation soldering. Among other things, Galden exhibits high temperature resistance, high resistance to reactive chemicals, low vapor pressure, no flash point, excellent heat transfer properties, good wetting properties and no chemical activity. Galden is not harmful to the ozone layer in the atmosphere and is not a hazardous substance in terms of occupational health and safety.

The above-mentioned object is also fulfilled by a method for operating the reflow condensation soldering machine mentioned above. The method comprises injecting vaporous perfluoropolyethers into a hermetically sealed process chamber containing an assembly to be soldered, heating the assembly by condensing the vaporous perfluoropolyether, sucking off condensed and vaporous perfluoropolyether including impurities, feeding the sucked-off material to a separating condensate trap which comprises the centrifuge or the disc separator and the means for condensing the perfluoropolyether, condensing and separating the perfluoropolyether from the impurities, and using the purified perfluoropolyether for a soldering operation for a subsequent assembly.

According to different embodiments, the disc separator can be operated intermittently or continuously. Since no purification (separation/regeneration) of the perfluoropolyether takes place during the soldering phase, during which the soldering process is carried out in the process chamber, the disc separator can be put into a resting state to protect the gearbox, motor, etc. In this case, the disc separator can be prefilled with purified or fresh perfluoropolyether after the end of the rest phase, preferably with 0.5-3 liters of perfluoropolyether, and particularly preferably with 0.9-1.1 liters of perfluoropolyether. As optimum separation conditions are only achieved when the separator is filled, the disc separator is pre-conditioned in this way and the purification process becomes more efficient.

If the main focus of the plant is on optimizing throughput or purification performance, the disc separator can also be operated continuously. To optimize the purification performance, for example, purified perfluoropolyether can be fed to the disc separator during a soldering phase. To optimize the throughput, vapor can be fed from a second process chamber, which operates at a different time from the first process chamber. If the disc separator is dimensioned accordingly, vapor from more than two process chambers, for example three, four or five process chambers, which perform the soldering process at different times, can also be processed in a continuously running disc separator.

### BRIEF DESCRIPTION OF THE DRAWINGS

The present invention is now described by means of the following Figures, in which

FIG. 1 shows a reflow condensation soldering machine with a circulation system of a heat transfer medium according to the state of the art,

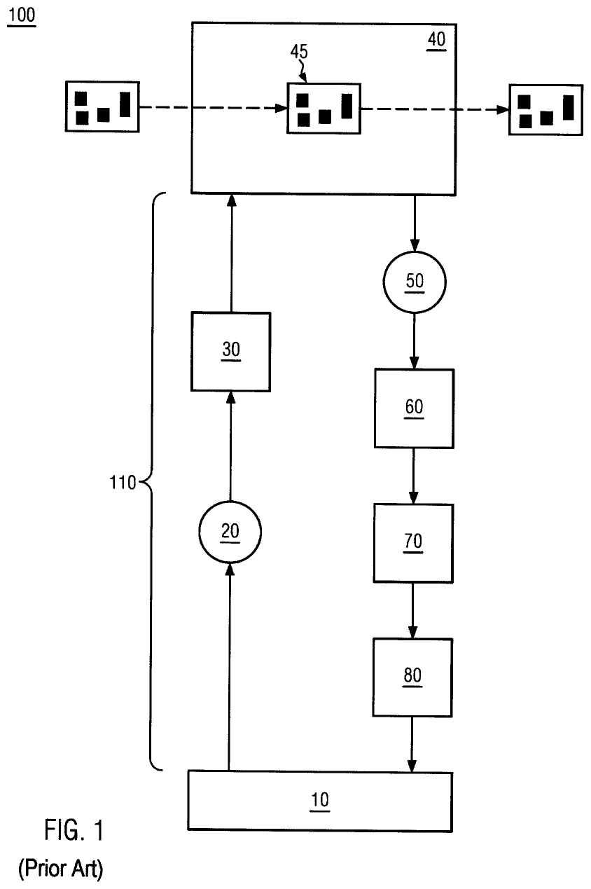

FIG. 2 shows a reflow condensation soldering machine with a circulation system of a heat transfer medium according to an embodiment of the present invention, and

FIG. 3 schematically shows a disc separator with integrated condensation device according to an embodiment of the present invention.

### DETAILED DESCRIPTION OF PREFERRED EMBODIMENTS

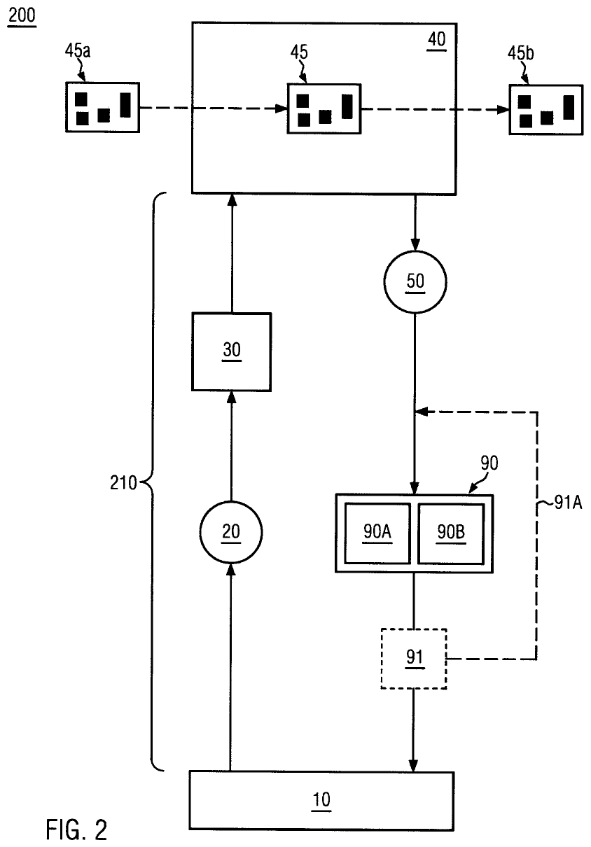

FIG. 2 shows a reflow condensation soldering machine 200 with a circulation system 210 for a heat transfer medium according to an embodiment of the present invention. The circulation system comprises a reservoir 10, a first pump 20, a heater 30, a process chamber 40, a second pump 50 and a separating condensate trap 90.

The first pump 20 pumps liquid heat transfer medium in the form of perfluoropolyether (PFPE) from the reservoir 10 to the heating means 30. In the heating means 30 the PFPE is vaporized and then fed to the process chamber 40. The medium (vaporous PFPE) then condenses on the printed circuit board 45 to be soldered and thus heats the components to be soldered on the printed circuit board 45 in the process chamber 40 and the soldering paste. The PFPE is adapted so that the boiling point of the PFPE is slightly higher than the melting point of the solder. This ensures that the soldering temperature is reached at the same time and that the components do not overheat during soldering, as the boiling temperature of the PFPE is also the maximum temperature. After this “soldering phase”, in a first phase of a “regeneration phase” or “separation phase”, both the components of the heat transfer medium in the vaporous and liquid aggregate state are sucked out of chamber 40 with a second pump 50. After the suction, condensation of the vaporous part of the heat transfer medium takes place in the separating condensate trap 90 and the heat transfer medium is separated from the residuals (impurities). Accordingly, the separating condensate trap 90 comprises a condensation device 90A and a separator 90B. During this “regeneration phase” the printed circuit board 45 is also freed from the PFPE coating, removed from the process chamber 40 and is available as product 45b. A new printed circuit board 45a is then placed in the process chamber 40 and a new “soldering phase” with recycled (remanufactured) PFPE can begin.

After condensation in the condensation device 90A, a mixture (emulsion) of liquid components (PFPE, flux, soldering paste, etc.) which are not soluble in each other is obtained. It is possible that even small amounts of solids of all impurity particles (for example tin particles) are contained. In the present invention a disc separator 90B is used to separate the liquid and solid components from the PFPE. A disc separator is a special type of centrifuge. The underlying idea of a centrifuge is based on the processes in a settling tank. There, particles, sediments and solids sink slowly to the bottom following the force of gravity, and liquids of different densities separate under the influence of gravity. However, this separation process is very slow. A separator is a sedimentation tank that rotates around an axis. When the entire unit rotates quickly, gravity is replaced by a controllable centrifugal force. By inserting special discs, the surface on which the different phases can settle is increased, which accelerates the separation process. Disc separators are known, for example, in the dairy industry to separate the cream from the milk.

Optionally (drawn in dashed line), the circulation system of the reflow condensation soldering machine can have a means 91, 91A, with which purified and liquid PFPE is returned to the separating condensate trap 90 during the soldering phase, so that the cooling process of the separating condensate trap 90 is accelerated and the PFPE is better purified. It must be noted that the soldering phase is also the cooling phase of the separating condensate trap 90. Furthermore, this means can be used in intermittent operation as well as in continuous operation. In continuous operation, this device is used for cooling and maintaining optimum separating conditions. In intermittent operation, i.e. when the separator is temporarily at rest, for example during a soldering phase, the device can be used to prefill the separator in order to create more reproducible separating conditions.

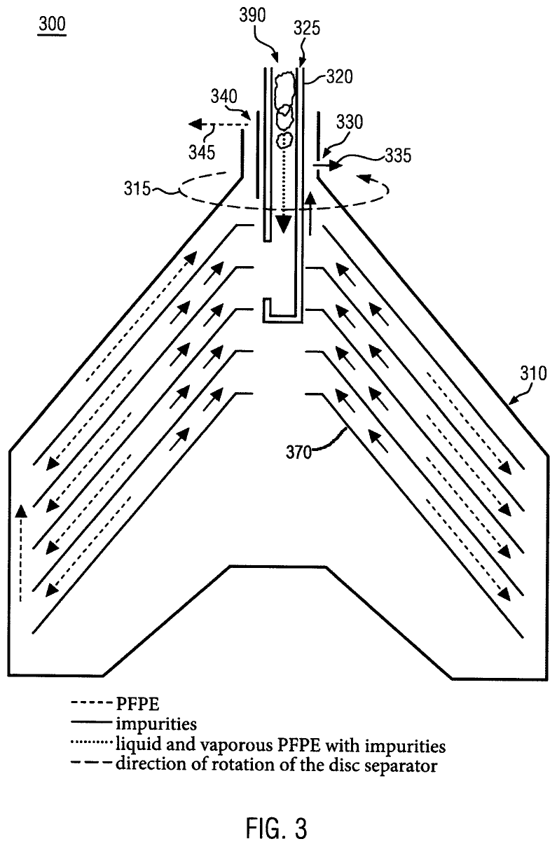

FIG. 3 exemplarily and schematically shows a cross-section of a disc separator as used in the present invention. FIG. 3 shows a disc separator 300 with a drum 310, an inlet 320, a first outlet 330, a second outlet 340 and a set of stacked discs 370. Separation in a disc separator occurs due to differences in density, which means that in the first outlet 330 the liquid with the relatively lower density can be discharged and in the second outlet 340 the liquid with the relatively higher density can be discharged. With the current applications and materials used, the PFPE has a higher density than the impurities, so in the illustration in FIG. 3, the first outlet 330 is for the impurities 335 and the second outlet 340 is for the purified PFPE 345. However, the present invention is not limited to this example. For example, in other applications materials may be used where the PFPE has a lower density than the impurities. In this case, the first outlet 330 would be for the purified PFPE and the second outlet 340 would be for the impurities. It is also possible that some of the impurities have a lower density than the PFPE and some have a higher density than the PFPE and/or additional solids. With appropriately designed disc separators, the fractions of the liquid phases can be separated. For example, the disc separator may have a sludge chamber in which the solids collect. To separate more than two liquid phases, for example, a plurality of separators can be connected in series. For example, if the condensed, unpurified heat transfer medium consists of a low density phase with impurities, a medium density PFPE phase and a high density phase with impurities, the purified PFPE can be extracted with two separators connected in series.

In the embodiment shown in FIG. 3, the inlet 320 is provided with a cavity through which a cooling liquid 325 can flow in the case of a design with active cooling. Alternatively, the inlet 320 can be in contact with a device that can dissipate heat in any suitable way, for example a heat pipe or fluid-cooled heat sink. However, FIG. 3 shall not be understood to mean that the present invention is limited to active cooling. As will be described in more detail below, instead of the cavity for the coolant or cooling liquid 325 shown in FIG. 3, in alternative designs the inlet can be solid, so that it has a correspondingly high heat capacity to absorb sufficient heat and provide passive cooling.

The material 390 (liquid and vaporous PFPE and impurities) pumped out of the process chamber by a pump reaches the inlet 320 of the disc separator 300. The vaporous PFPE condenses on the walls of the cooled inlet 320 and then enters the interior of the disc separator together with the liquid PFPE and the impurities. The components separate due to the centrifugal forces caused by the rotation of the separator (interrupted circular arrow 315), so that the heavy PFPE is forced outwards (arrows 345) and the lighter impurities are forced inwards (arrows 335). Separate outlets 330 and 340 then separate the purified PFPE and the impurities.

FIG. 3 shows a particularly advantageous embodiment of a separating condensate trap for a reflow condensation soldering machine. By integrating a separating condensate trap into the circuit of the heat transfer medium, the separation of PFPE and impurities is accelerated. The disc separator used in this process fulfills a double function: gaseous heat transfer medium condenses and impurities contained in the condensate are separated. The condensation of the heat transfer medium is achieved by limiting the maximum temperature of the separator components (e.g. inlet, float, disc, drum). The limitation of the temperature can be achieved by active cooling and/or by a high mass of the discs, drum, inlet and/or other components in relation to the flow rate. The separation of impurities is achieved by two main mechanisms. Firstly, the condensation temperature of the PFPE is higher than that of the impurities, so that the PFPE condenses first and the pure PFPE flows out through the separator. Secondly, the difference in density between the PFPE and the impurities is exploited, so that separation of the two condensates for temperatures below the condensation temperature of the impurities takes place via the centrifugal forces. By means of this separating condensate trap the separation of the PFPE and the impurities can be accelerated. Thus, the heat transfer medium bound in the machine can be made available to the process again more quickly and an increase in the plant throughput is made possible.

It should be noted that the integration of the condensation into the disc separator is particularly advantageous, since the condensation already causes a pre-separation, which is then further refined by the disc centrifuge/disc separator. This makes the separation process more efficient, i.e. more accurate. However, it is also possible to separate condensation in a special condensation device from separation in a disc separator.

Passive cooling can take advantage of the fact that separation in a reflow condensation soldering machine is not continuous, but is suspended during the soldering process times and can cool down during this time. If the components of the disc separator are equipped with a sufficiently large thermal mass, corresponding to the expected flow rates and flow times, to absorb the thermal energy during condensation during a “regeneration phase”, and if the components of the disc separator are still designed in such a way that they can release the previously absorbed heat quantity to the environment during the “soldering phase”, neither an upstream condensation device nor an internal active cooling system is necessary.

The cooling process can be supported, for example, by introducing condensed and purified PFPE into the disc separator during the soldering phase, i.e. the phase during which no vapor is introduced into the separator. For example, the condensate purified during the separation phase can be collected in the means marked with the reference numeral 91 in FIG. 2 and returned to the disc separator 300 shown in FIG. 3 via a return 91 A (only shown in FIG. 2) during the soldering phase. On the one hand, this ensures that the hydrodynamic separation conditions always remain the same, as the disc separator does not run empty. Furthermore, by feeding in the condensed and purified PFPE, the heat stored in the condensation device is removed more quickly. Finally, the condensed and purified PFPE is subjected to a new separation so that maintenance cycles can be increased. This support of the cooling process is possible for both passive and active cooling.

Another way to maintain continuous operation of the disc separator would be to continuously feed vapor into the disc separator, for example from two or more separate process chambers which, offset from each other, carry out the soldering process and the regeneration process. To ensure heat dissipation in this case of a continuously operated disc separator with integrated condensation device, the thermal conductivity of the heat dissipating components must be sufficiently high.

When designing the disc separator, the number, shape, structure and arrangement of the discs, the volume of the separator, the geometry of the inlet and the speed of rotation can be designed in such a way that a specific plant throughput can be achieved with a specific purification performance, taking into account the properties of the contaminated heat transfer medium. For example, depending on particle sizes and the density of the particles, an optimum disc spacing can be selected which is in the range of 0.2 mm to 14 mm. The number of discs, the speed of rotation and the volume of the disc separator determine the separation efficiency, i.e. how much heat transfer medium is purified to a certain degree in a certain time unit. Typical reflow condensation soldering machines with a circulation system for the heat transfer medium contain 20-40 liters of heat transfer medium, of which 1-6 liters are consumed in one soldering process run, which must then be purified after the soldering process. Usually 4-250 discs are used, which rotate at up to 30,000 revolutions per minute. For use in reflow condensation soldering machines with a circulation system for the heat transfer medium, at least 50 discs rotating at least 10,000 rpm are preferred. The inlet is advantageously designed in such a way that condensation takes place in the inlet and an associated pre-separation takes place.

What is claimed is:

1. Reflow condensation soldering machine comprising a circulation system for a heat transfer medium, wherein the circulation system comprises a centrifuge and a condensation device for the heat transfer medium.

2. Reflow condensation soldering machine according to claim 1, wherein the centrifuge is a disc separator.

3. Reflow condensation soldering machine according to claim 2, wherein the disc separator has a number of discs, and disc spacing and the speed of rotation of the disc separator is adapted to achieve a desired plant throughput, taking into account expected particle sizes of impurities of the heat transfer medium and viscosity of the contaminated heat transfer medium.

4. Reflow condensation soldering machine according to claim 3, wherein the disc separator comprises 4 to 250 discs.

5. Reflow condensation soldering machine according to claim 3, wherein the disc spacing between the discs is in the range of 0.2 mm-14 mm.

6. Reflow condensation soldering machine according to claim 5, wherein the discs are equally spaced.

7. Reflow condensation soldering machine according to claim 5, wherein the spacing between the discs in the inlet area is smaller or larger than at the end of a stack of the discs opposite the inlet area.

8. Reflow condensation soldering machine according to claim 1, wherein the centrifuge is adapted to perform 1-150,000 revolutions per minute, preferably 1,000 to 10,000 revolutions per minute.

9. Reflow condensation soldering machine according to claim 1, wherein the centrifuge is adapted to process 1-6 liters of condensed heat transfer medium.

10. Reflow condensation soldering machine according to claim 1, wherein the condensation device for the heat transfer medium is integrated in the centrifuge.

11. Reflow condensation soldering machine according to claim 10, wherein the condensation device for the heat transfer medium comprises temperature limiting means of one or more components of the centrifuge.

12. Reflow condensation soldering machine according to claim 11, wherein the temperature limiting means comprises active cooling of the one or more components of the centrifuge.

13. Reflow condensation soldering machine according to claim 11, wherein the temperature limiting means comprises passive cooling of the one or more components of the centrifuge.

14. Reflow condensation soldering machine according to claim 13, further comprising means for supplying purified PFPE during a cooling phase of passive cooling of the centrifuge.

15. Reflow condensation soldering machine according to claim 11, wherein the centrifuge is a disc separator and one or more components of the disc separator comprises at least one of the following:
an inlet of the disc separator, a float of the disc separator, one or a plurality of separator discs, a separator drum.

16. Reflow condensation soldering machine according to claim 12, wherein a wall of said one or plurality of components has at least one cavity through which a cooling fluid can flow.

17. Reflow condensation soldering machine according to claim 12, wherein a heat pipe is integrated in a wall of the one or more components.

18. Reflow condensation soldering machine according to claim 13 wherein at least one component of said one or more components is configured such that a heat capacity of the at least one component is sufficient to absorb a quantity of heat of the vaporous heat transfer medium flowing past during a predetermined separation phase so that the heat transfer medium condenses.

19. Reflow condensation soldering machine according to claim 1, wherein the heat transfer medium has a boiling point of 260° C.

20. Reflow condensation soldering machine according to claim 1, wherein the heat transfer medium is Galden or PFPE.

21. Method of operating the reflow condensation soldering machine according to claim 1, comprising:
injecting vaporous perfluoropolyethers into a hermetically sealed first process chamber containing an assembly to be soldered,
heating the assembly by condensing the vaporous perfluoropolyether,
suction of condensed and vaporous perfluoropolyethers including impurities,
feeding the condensed and vaporous perfluoropolyethers including impurities to a separating condensate trap comprising a disc separator and condensing device for condensing the perfluoropolyether,
condensing and separating the perfluoropolyether from the impurities with the separating condensate trap, and
using a purified perfluoropolyether for a soldering process for a subsequent assembly.

22. Method according to claim 21, in which the disc separator is brought into a rest state during a soldering phase and in which the disc separator is prefilled with the purified or a fresh perfluoropolyether after the end of the rest phase, preferably with 0.5-3 liters of perfluoropolyether, and particularly preferably with 0.9-1.1 liters of perfluoropolyether.

23. Method according to claim 21, in which the disc separator is operated continuously, wherein the purified perfluoropolyether or vapor from a second process chamber, which operates with a time offset relative to the first process chamber, is fed to the disc separator during a soldering phase.
